(19) United States
(12) Patent Application Publication
(10) Pub. No.: US 2020/0020330 A1
(43) Pub. Date: Jan. 16, 2020

(54) DETECTING VOICE-BASED ATTACKS AGAINST SMART SPEAKERS

(71) Applicant: QUALCOMM Incorporated, San Diego, CA (US)

(72) Inventors: Xu GUO, San Jose, CA (US); Arvind KRISHNASWAMY, San Jose, CA (US); Liang CAI, San Diego, CA (US); Nabanita SEN, Cupertino, CA (US); Jyotsna KRISHNASWAMY, Chandler, AZ (US); Kenneth CHEN, San Diego, CA (US)

(21) Appl. No.: 16/036,538

(22) Filed: Jul. 16, 2018

(51) Int. Cl. G10L 15/22; G10L 17/06; G01R 31/00

(52) U.S. Cl. CPC G10L 15/22; G01R 31/002; G10L 17/06

(57) ABSTRACT

Techniques for operating a voice-activated computing device are provided. These techniques can be used to prevent voice-based attacks on such devices. An example method according to these techniques includes receiving audio content comprising a voice command, monitoring electromagnetic (EM) emissions using an EM detector of the voice-activated computing device, determining whether the audio content comprising the voice command was generated electronically or was issued by a human user based on the EM emissions detected while receiving the audio content comprising the voice command, and preventing the voice command from being executed by the voice-activated computing device responsive to determining that the voice command was generated electronically.

### BACKGROUND

Smart speakers are computing devices that are configured to receive voice commands that allow user to interact with the device. The device may include an integrated virtual assistant for processing voice commands and/or may rely on a remote server to process the voice commands received at the device. Smart speakers can be used to interact with the various online services. A user may use a smart speaker to search for and receive information from network-connected service providers. The user may also conduct sensitive transactions with financial service providers, medical information providers, and/or providers of goods or services. Some smart speakers are configured to provide audio content only, while others may include screens that provide an interface for interacting with the smart speaker and may be used to display text, image, and/or video content. Smart speakers may also be configured to include home automation features that allow the user to control lighting, security, heating and ventilation systems, smart appliances, and/or other automated features within a home or business. As smart speakers become a ubiquitous feature in many homes and/or businesses, these devices have become a target for attackers attempting to exploit these devices to fraudulently obtain goods or services, conduct fraudulent financial transactions, and/or fraudulently obtain other sensitive information.

### SUMMARY

An example method for operating a voice-activated computing device according to the disclosure includes receiving audio content comprising a voice command, monitoring electromagnetic (EM) emissions using an EM detector of the voice-activated computing device, determining whether the audio content comprising the voice command was generated electronically or was issued by a human user based on the EM emissions detected while receiving the audio content comprising the voice command, and preventing the voice command from being executed by the voice-activated computing device responsive to determining that the voice command was generated electronically.

Implementations of such a method can include one or more of the following features. Determining whether the audio content comprising the voice command was issued electronically or by a human user includes correlating changes in the audio content comprising the voice command with changes in the EM emissions detected by the EM detector to determine a security indicator, and determining whether the voice command was generated electronically based on the security indicator. The changes in the audio content comprise changes in at least one of the volume and the frequency of the audio content. Calibrating the EM detector to generate baseline EM emissions, and correlating the changes in the audio content comprising the voice command with changes in the EM emissions includes subtracting the baseline EM emissions from the EM emissions before correlating the changes in the audio content with the changes in the EM emissions. Calibrating the EM detector to generate the baseline EM emissions includes detecting EM emissions generated by the voice-activated computing device. Determining that the voice command was generated electronically responsive to the security indicator exceeding a predetermined threshold. Determining whether the audio content comprising the voice command was issued electronically or by a human user includes sending the audio content and information regarding the EM emissions to a remote server for analysis, and receiving an indication from the server whether the voice command was generated electronically or by a human user from the remote server. Determining whether the audio content comprising the voice command was issued electronically or by a human user includes receiving an indication from the EM detector that the EM detector has detected abnormal EM variations.

An example voice-activated computing device according to the disclosure includes means for receiving audio content comprising a voice command using means for receiving sound, means for monitoring electromagnetic (EM) emissions, means for determining whether the audio content comprising the voice command was generated electronically or was issued by a human user based on the EM emissions detected while receiving the audio content comprising the voice command, and means for preventing the voice command from being executed by the voice-activated computing device responsive to determining that the voice command was generated electronically.

Implementations of such a voice-activated computing device can include one or more of the following features. The means for determining whether the audio content comprising the voice command was issued electronically or by a human user include means for correlating changes in the audio content comprising the voice command with changes in the EM emissions detected by the means for detecting EM emissions to determine a security indicator, and means for determining whether the voice command was generated electronically based on the security indicator. The changes in the audio content comprise changes in at least one of the volume, the frequency, the cadence, and the voice pattern of the audio content. Means for calibrating the means for detecting EM emissions to generate baseline EM emissions; and the means for correlating the changes in the audio content comprising the voice command with changes in the EM emissions further include means for subtracting the baseline EM emissions from the EM emissions before correlating the changes in the audio content with the changes in the EM emissions. The means for calibrating the means for detecting EM emissions to generate the baseline EM emissions includes means for detecting EM emissions generated by the voice-activated computing device. Means for determining that the voice command was generated electronically responsive to the security indicator exceeding a predetermined threshold. The means for determining whether the audio content comprising the voice command was issued electronically or by a human user includes means for sending the audio content and information regarding the EM emissions to a remote server for analysis, and means for receiving an indication from the server whether the voice command was generated electronically or by a human user from the remote server. The means for determining whether the audio content comprising the voice command was issued electronically or by a human user further includes means for receiving an indication from the EM detector that the EM detector has detected abnormal EM variations.

An example voice-activated computing device according to the disclosure includes an electromagnetic (EM) detector configured to monitor for EM emissions, a microphone, and a processor communicatively coupled to the EM detector and the microphone. The processor configured to receive audio content comprising a voice command using the microphone, monitor electromagnetic (EM) emissions using the EM detector, determine whether the audio content comprising the voice command was generated electronically or was issued by a human user based on the EM emissions detected while receiving the audio content comprising the voice command, and prevent the voice command from being executed by the voice-activated computing device responsive to determining that the voice command was generated electronically.

Implementations of such a voice-activated computing device can include one or more of the following features. The processor being configured to determine whether the audio content comprising the voice command was issued electronically or by a human user is further configured to correlate changes in the audio content comprising the voice command with changes in the EM emissions detected by the EM detector to determine a security indicator, and determine whether the voice command was generated electronically based on the security indicator. The changes in the audio content comprise changes in at least one of the volume, the frequency, the cadence, and the voice pattern of the audio content. The processor is further configured to calibrate the EM detector to generate baseline EM emissions; and the processor being configured to correlate the changes in the audio content comprising the voice command with changes in the EM emissions is further configured to subtract the baseline EM emissions from the EM emissions before correlating the changes in the audio content with the changes in the EM emissions. The processor being configured to calibrate the EM detector to generate the baseline EM emissions is further configured to detect, using the EM detector, EM emissions generated by the voice-activated computing device. The processor is further configured to determine that the voice command was generated electronically responsive to the security indicator exceeding a predetermined threshold. The processor being configured to determine whether the audio content comprising the voice command was issued electronically or by a human user is further configured to send the audio content and information regarding the EM emissions to a remote server for analysis, and receive an indication from the server whether the voice command was generated electronically or by a human user from the remote server. The processor being configured to determine whether the audio content comprising the voice command was issued electronically or by a human user is further configured to receive an indication from the EM detector that the EM detector has detected abnormal EM variations.

An example non-transitory, computer-readable medium, having stored thereon computer-readable instructions for operating a voice-activated computing device, according to the disclosure includes instructions configured to cause the voice-activated computing device to receive audio content comprising a voice command, monitor electromagnetic (EM) emissions using an EM detector of the voice-activated computing device, determine whether the audio content comprising the voice command was generated electronically or was issued by a human user based on the EM emissions detected while receiving the audio content comprising the voice command, and prevent the voice command from being executed by the voice-activated computing device responsive to determining that the voice command was generated electronically.

Implementations of such a non-transitory, computer-readable medium can include one or more of the following features. The code to cause the voice-activated computing device to determine whether the audio content comprising the voice command was issued electronically or by a human user further comprise instructions configured to cause the voice-activated computing device to correlate changes in the audio content comprising the voice command with changes in the EM emissions detected by the EM detector to determine a security indicator, and determine whether the voice command was generated electronically based on the security indicator. The changes in the audio content comprise changes in at least one of the volume, the frequency, the cadence, and the voice pattern of the audio content. Instructions configured to cause the voice-activated computing device to calibrate the EM detector to generate baseline EM emissions; and the Instructions configured to cause the voice-activated computing device to correlate the changes in the audio content comprising the voice command with changes in the EM emissions further comprise Instructions configured to cause the voice-activated computing device to subtract the baseline EM emissions from the EM emissions before correlating the changes in the audio content with the changes in the EM emissions. Instructions configured to cause the voice-activated computing device to calibrating the EM detector to generate the baseline EM emissions includes instructions configured to cause the voice-activated computing device to detect EM emissions generated by the voice-activated computing device. Instructions configured to cause the voice-activated computing device to determine that the voice command was generated electronically responsive to the security indicator exceeding a predetermined threshold.

### BRIEF DESCRIPTION OF THE DRAWING

FIG. 1 is a schematic diagram of an example operating environment that includes a voice-activated computing device that may be used to implement the techniques disclosed herein, in accordance with certain example implementations.

FIG. 2 is a functional block diagram of an example computing device that can be used to implement the voice-activated computing device illustrated in FIG. 1.

FIG. 3 is an example process for operating a voice-activated computing device according to the disclosure.

FIG. 4 is an example process for determining whether a voice command was generated electronically according to the disclosure.

FIG. 5 is an example process for calibrating an electromagnetic detector to generate baseline data was generated electronically according to the disclosure.

FIG. 6 is an example process for calibrating an electromagnetic detector to generate baseline data was generated electronically according to the disclosure.

FIG. 7 is an example process for determining whether a voice command was generated electronically according to the disclosure.

FIG. 8 is an example process for determining whether a voice command was generated electronically according to the disclosure.

FIG. 9 is an example process for determining whether a voice command was generated electronically according to the disclosure.

FIGS. 10A and 10B are diagrams illustrating an example loudspeaker according to the disclosure.

FIG. 11 is a functional block diagram of an example electromagnetic detector according to the disclosure.

Like reference symbols in the various drawings indicate like elements, in accordance with certain example implementations.

### DETAILED DESCRIPTION

Techniques for detecting and preventing voice-based attacks on smart speakers and other voice-activated computing devices are provided. The techniques disclosed herein can distinguish between electronically-generated voice commands and voice commands that were issued by a human user. Electronically-generated voice commands can be identified by analyzing electromagnetic (EM) emissions detected while audio content that includes voice-command is received and correlating changes in the EM emissions with changes in the audio content. For electronically-generated voice commands, changes in the volume, frequency, cadence, voice pattern and/or other aspects of the audio content comprising the voice command that correlate with changes in EM emission can be indicative of the voice command being generated electronically from loudspeaker of the voice-activated computing device or another device. Human-generated voice commands will not exhibit the EM fluctuations that are indicative of a voice command having been electronically generated.

The techniques disclosed herein can be used to detect and prevent voice-based attacks on smart speakers and other voice-activated computing devices. One such attack directly attacks the voice-based computing device to assume control over a speaker of the voice-based computing device. The attacker may introduce malicious software onto the voice-based computing device that is configured to record and playback voice commands that were issued by a user of the voice-based computing device. The malicious software can be configured to record and play back security passcodes and/or other authentication credentials required to access the content and/or services that the attacker wishes to access. The malicious software can also be configured to implement machine learning techniques to synthesize voice commands that the user of the smart speaker has not vocalized. The malicious software can also be configured to generate hidden voice commands that are inaudible to a human but may be detectable and acted upon by the voice-activated computing device. The malicious software can even be configured to generate garbled sounds that include hidden voice commands.

The techniques disclosed herein can be used to detect such attacks and to prevent voice commands entered as part of such an attack from being executed by the voice-activated computing device. The voice-activated computing device can include an EM detector that is configured to detect EM emissions including those that are generated by the speaker of the voice-activated computing device when the speaker is outputting audio content. The voice-activated computing device can be configured to calibrate the EM detector to generate baseline EM emissions information that can be compared to EM emissions detected while a voice-based command is issued to the voice-activated computing device. The baseline EM emissions include environmental noise that may be generated by other devices proximate to the voice-activated computing device, emissions generated by the build-in speaker of the voice-activated computing device, and/or other EM emissions sources. The voice-activated computing device can be configured to correlate changes in the volume, frequency, cadence, voice pattern and/or other aspects of the audio content comprising the voice command received by a microphone of the voice-activated computing device to make a determination whether the voice command was issued electronically or by a human user.

Another type of threat that the techniques disclosed herein can detect and prevent from issuing commands to the voice-activated computing device are situations where an attacker has compromised the loudspeaker of a device proximate to the voice-activated computing device and uses that loudspeaker to issue commands to the voice-activated computing device. The loudspeaker may be part of a television, computing device, smartphone, and/or other type of device that includes a loudspeaker for outputting audio content. A hacker may introduce malicious code into or otherwise induce the device to broadcast voice commands to the voice-activated computing device. The voice command may be embedded in audio or video content that is broadcast, streamed, downloaded, or being played from media on the device. The voice commands may also be inaudible to humans and/or may be embedded in garbled sounds to render the voice commands inaudible. The detection range of the EM detector is determined by the antenna and the amplifier of the EM detector and can be configured to detect electronically-generated voice commands from other devices that are proximate to the voice-activated computing device. The techniques disclosed herein can be used to detect such an attack and to prevent voice commands received as part of such an attack from being executed.

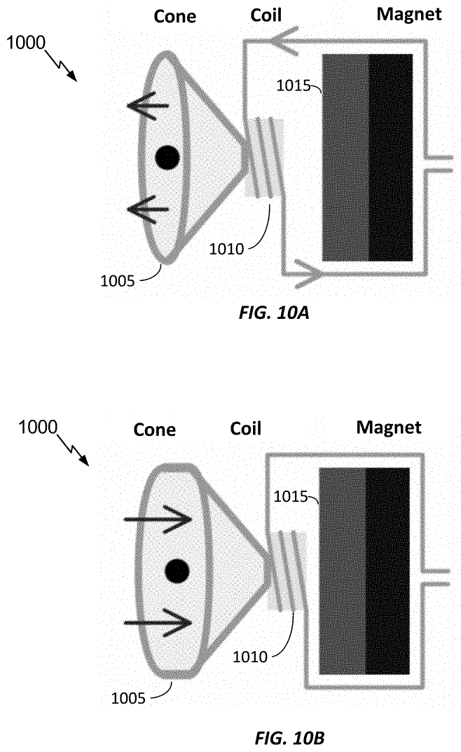

FIGS. 10A and 10B illustrate an example loudspeaker that includes a cone 1005, a coil 1010, and a permanent magnet 1015. Such a loudspeaker may be integrated into a voice-activated computing device or could be included in another device which is used by an attacker to generate voice-commands in an attempt to control the voice-activated computing device. When a fluctuating electric current flows through the coil 1010, the coil 1010 becomes a temporary electromagnet that is attracted and repelled by the permanent magnet 1015, which causes the coil 1010 to move relative to the permanent magnet 1015. An inner portion of the cone 1005 is affixed to the coil 1010, and an outer portion of the cone 1005 is fixed to a frame or other stationary portion of the loudspeaker. As the coil 1010 moves, the inner portion of the cone 1005 moves causing the cone 1005 to generate the sound output by the loudspeaker. Louder sounds can be generated by inputting a larger electrical pulses into the coil 1010, and softer sounds can be generated by inputting smaller electrical pulses into the coil 1010. The magnetic field strength emitted by a loudspeaker similar to the example loudspeaker illustrated in this example typically ranges from 30-210 μT (microteslas). The speaker generates electromagnetic variations during operating that can be detected using various means, such as an EM detector, a magnetometer, and/or other sensing means.

The techniques disclosed herein can monitor electromagnetic variations occurring during voice command inputs and apply correlation analysis to the EM variations and changes in one or more attributes of audio content that may comprise a voice command to determine whether the voice command was issued by human user or was likely to have been issued electronically. Changes in the volume, the frequency, the cadence, and the voice pattern for voice commands issued electronically through a speaker, such as that illustrated in FIGS. 10A and 10B, may cause bigger variations in the magnetic field generated by the loudspeaker. Higher pitched sounds have a higher frequency and cause the coil 1010 of the loudspeaker to move more quickly. Louder sounds cause the speaker to move more than sounds having a lower volume. Cadence of the voice input (also referred to herein as “speech tempo”) can refer to the number of syllables or other units of pronunciation that are uttered over a predetermined period of time. A correlation between the pattern of syllables or other units pronunciation of the voice command and electromagnetic (EM) variations can indicate that the voice command was issued electronically. The voice pattern can refer to the pattern of syllables, words, or other units of pronunciation and pauses between these units of pronunciation. The pattern of such utterances can be correlated with periods of greater electromagnetic (EM) variation, while pauses can be correlated with periods of lesser EM variation. Such a correlation should not exist for voice commands that are issued by a human user and is indicative of the voice command having been issued electronically.

Variations in the magnetic field can be monitored at the voice-activated computing device using a built-in magnetometer or other sensor capable of detecting changes in the magnetic field surrounding the voice-activated computing device. The voice-activated computing device can also include an electromagnetic (EM) detector instead of or in addition to the magnetometer or other sensor. The EM detector can be configured to be more sensitive to variations in the magnetic field proximate to the voice-activated computing device and can provide a greater detection range that may otherwise be possible using just the built-in magnetometer or other sensor capable of detecting changes in the magnetic field. The variations in the magnetic field can be correlated with changes in the audio input that includes the voice-command(s) detected by the voice-activated computing device. The voice-activated computing device can be configured to generate a correlation score, where a higher correlation between fluctuations in the magnetic field and changes in the volume, frequency, or other attributes of the voice-command is indicative of the voice command having been electronically issued using a loudspeaker. The example loudspeaker illustrated in FIGS. 10A and 10B is an example of one type of loudspeaker that may be used with the techniques disclosed herein. Other types of loudspeakers that generate similar fluctuations in the magnetic field can also be used.

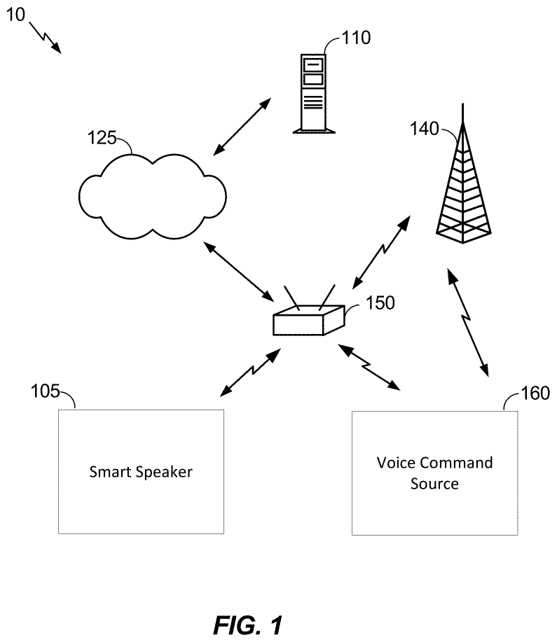

FIG. 1 is a schematic diagram of an example operating environment 10 that includes a voice-activated computing device 105 that may be used to implement the techniques disclosed herein. The voice-activated computing device 105 is also referred to herein as a “smart speaker” but the voice-activated computing device 105 is not limited to just a smart speaker. The voice-activated computing device 105 can be various types of computing devices, including but not limited to, a tablet computer, mobile phone, smartphone, game console, and/or other types of voice-activated computing devices. Furthermore, in some implementations, the voice-activated computing device 105 may be a computing device that is substantially stationary, such as a computer server, set top box, or other computing device that includes a voice-activated user interface.

The voice-activated computing device 105 can include an electromagnetic (EM) detector and/or other type of sensor(s) configured to detect EM emissions. The voice-activated computing device can also include a microphone for capturing audio content that may comprise one or more voice commands. Human-generated voice commands will not exhibit the EM fluctuations that are associated with electronically generated audio content.

The operating environment 10 may include a voice command source 160. The voice command source is an electronic device capable of generating audio output that can include voice commands that can be received by the voice-activated computing device 105. The voice command source 160 can comprise a television, computing device, smartphone, and/or other type of device that includes a loudspeaker for outputting audio content. As discussed in the preceding examples, a hacker may introduce malicious code into or otherwise induce the voice command source 160 to broadcast voice commands that may be detected by the voice-activated computing device 105 in an attempt to cause the voice-activated computing device 105 to execute the voice commands. In some operating environments, the voice command source 160 may be a component of the voice-activated computing device. A hacker may introduce malicious software into the voice-activated computing device 105 and assume control over the loudspeaker of the voice-activated computing device 105 to output audio content comprising voice commands in an attempt to cause the voice-activated computing device to execute the voice commands.

The operating environment 10 may include one or more wireless access points 150 and/or one or more wireless access points 140. The one or more wireless access points 150 and/or the one or more wireless base stations are configured to provide wireless network connectivity to the voice-activated computing device 105. The wireless access points 150 and 140 are configured to provide connectivity via a network 125 (e.g., a cellular wireless network, a Wi-Fi network, a packet-based private or public network, such as the public Internet). The voice-activated computing device 105 may be configured, in some embodiments, to operate and interact with multiple types of other communication systems/devices, including local area network devices (or nodes), such as WLAN for indoor communication, femtocells, Bluetooth® wireless technology-based transceivers, and other types of indoor communication network nodes, wide area wireless network nodes, satellite communication systems, etc., and as such the voice-activated computing device 105 may include one or more interfaces to communicate with the various types of communications systems.

The operating environment 10 may further include a server 110 configured to communicate, via a network 125, or via wireless transceivers included with the server 110, with multiple network elements or nodes, and/or computing devices. For example, the server 110 may be configured to provide content accessible by the voice-activated computing device 105, such as downloadable application content, navigation data, browser-accessible content, and or access to other types of data. The server 110 can be configured to receive sensor data from the voice-activated computing device 105 associated with audio content that includes a voice command. The server 110 can be configured analyze the sensor data and the audio content to make a determination whether a voice command was generated electronically or was issued by a human user. This determination can be based on correlating fluctuations in electromagnetic (EM) emissions detected by the voice-activated computing device 105 with changes to one or more attributes in the audio content, such as changes in pitch or frequency. The voice-activated computing device 105 can be configured to analyze the audio and EM emissions data without relying on the server 110 in some implementations.

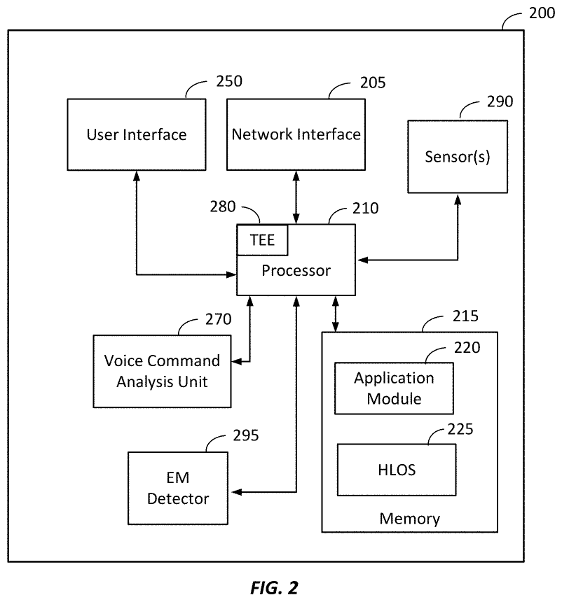

FIG. 2 is a functional block diagram of an example computing device 200 that can be used to implement various computing devices disclosed herein, such as the voice-activated computing device 105 discussed in the preceding example implementation. For the sake of simplicity, the various features/components/functions illustrated in the schematic boxes of FIG. 2 can be connected together using a common bus or are can be otherwise operatively coupled together. Other connections, mechanisms, features, functions, or the like, may be provided and adapted as necessary to operatively couple and configure a computing device 200. Furthermore, one or more of the features or functions illustrated in the example of FIG. 2 may be further subdivided, or two or more of the features or functions illustrated in FIG. 2 may be combined. Additionally, one or more of the features or functions illustrated in FIG. 2 may be excluded.

As shown, the computing device 200 can include a network interface 205 that can be configured to provide wired and/or wireless network connectivity to the computing device 200. The network interface can include one or more local area network transmitters, receivers, and/or transceivers that can be connected to one or more antennas (not shown). The one or more local area network transmitters, receivers, and/or transceivers comprise suitable devices, circuits, hardware, and/or software for communicating with and/or detecting signals to/from one or more of the wireless local area network (WLAN) access points, and/or directly with other wireless computing devices within a network. The network interface 205 can also include, in some implementations, one or more wide area network transmitters, receivers, and/or transceivers that can be connected to the one or more antennas (not shown). The wide area network transmitters, receivers, and/or transceivers can comprise suitable devices, circuits, hardware, and/or software for communicating with and/or detecting signals from one or more of, for example, the wireless wide area network (WWAN) access points and/or directly with other wireless computing devices within a network. The network interface 205 can include a wired network interface in addition to one or more of the wireless network interfaces discussed above. The network interface 205 can be used to receive data from and send data to one or more other network-enabled devices via one or more intervening networks.

The processor(s) (also referred to as a controller) 210 may be connected to the memory 215, the voice command analysis unit 270, the user interface 250, and the network interface 205. The processor may include one or more microprocessors, microcontrollers, and/or digital signal processors that provide processing functions, as well as other calculation and control functionality. The processor 210 may be coupled to storage media (e.g., memory) 215 for storing data and software instructions for executing programmed functionality within the computing device. The memory 215 may be on-board the processor 210 (e.g., within the same integrated circuit package), and/or the memory may be external memory to the processor and functionally coupled over a data bus.

A number of software modules and data tables may reside in memory 215 and may be utilized by the processor 210 in order to manage, create, and/or remove content from the computing device 200 and/or perform device control functionality. Furthermore, components of the high level operating system (“HLOS”) 225 of the computing device 200 may reside in the memory 215. As illustrated in FIG. 2, in some embodiments, the memory 215 may include an application module 220 which can implement one or more applications. It is to be noted that the functionality of the modules and/or data structures may be combined, separated, and/or be structured in different ways depending upon the implementation of the computing device 200. The application module 220 can comprise one or more trusted applications that can be executed by the trusted execution environment 280 of the computing device 200.

The application module 220 may be a process or thread running on the processor 210 of the computing device 200, which may request data from one or more other modules (not shown) of the computing device 200. Applications typically run within an upper layer of the software architectures and may be implemented in a rich execution environment of the computing device 200 (also referred to herein as a “user space”), and may include games, shopping applications, content streaming applications, web browsers, location aware service applications, etc. The application module 220 can be configured to comprise one or more applications that can be executed on the computing device 200. The application module 220 can be configured to provide a voice-command interface that allows a user of the computing device 200 to issue commands to control the operation of the one or more applications.

The processor 210 includes a trusted execution environment (TEE) 280. The trusted execution environment 280 can be used to implement a secure processing environment for executing secure software applications. The trusted execution environment 280 can be implemented as a secure area of the processor 210 that can be used to process and store sensitive data in an environment that is segregated from the rich execution environment in which the operating system and/or applications (such as those of the application module 220) may be executed. The trusted execution environment 280 can be configured to execute trusted applications that provide end-to-end security for sensitive data by enforcing confidentiality, integrity, and protection of the sensitive data stored therein. The trusted execution environment 280 can be used to store encryption keys, authentication information, and/or other sensitive data. The trusted applications implemented in the trusted execution environment 280 can be configured to provide a voice-command interface that allows a user of the computing device 200 to control the operation of the one or more applications. The trusted applications may also be used to conduct financial transactions, access sensitive data (e.g. medial or financial data associated with user of the device or with proprietary information associated with a company with which the user of the device works), and/or perform other operations of a sensitive nature. In some implementations, some or all of the functionality associated with the trusted applications may be implemented by untrusted applications operating in a rich execution environment of the computing device 200.

The computing device 200 may further include a user interface 250 providing suitable interface systems for outputting audio and/or visual content, and for facilitating user interaction with the computing device 200. For example, the user interface 250 of a typical smart speaker includes a least a microphone for receiving audio input and a speaker for outputting audio content. The computing device 200 is not limited to a smart speaker and some smart speakers may include user interface components in addition to a microphone and speaker. The computing device 200 may include additional user interface components, such as a keypad and/or a touchscreen for receiving user inputs, and a display (which may be separate from the touchscreen or be the touchscreen) for displaying visual content.

The computing device can include sensor(s) 290. The sensor(s) 290 can include an audio sensor and/or other means for detecting sounds including audio content that includes one or more voice commands. Such sensors may be included in addition to a microphone that is part of the user interface 250. The sensor(s) 290 can also include a magnetometer and can include one or more accelerometers.

The magnetometer can comprise a magnetoresistive permalloy sensor, which is used in some types of smart phones, tablet computing devices, and other types of handheld computing devices. For example, some commonly used magnetometers can be configured to measure magnetic fields within ±2 gauss (i.e., 200 microtesla) and is sensitive to magnetic fields magnetic fields of less than 100 microgauss (i.e., 0.01 microtesla).

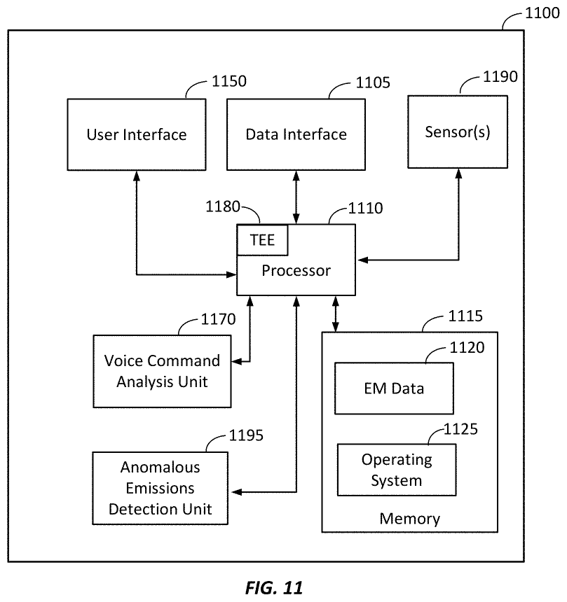

The electromagnetic (EM) detector 295 is configured to detect EM emissions. The EM detector can be used to detect variations in EM emissions generated by a speaker of an electronic device that is used to electronically issue a voice command to the computing device 200 according to the techniques disclosed herein. The EM detector 295 can be implemented a separate chip or module that can be connected to a system on a chip (SoC), chipset, or other processing means of the computing device 200. The EM detector 295 may be disposed on the same printed circuit board as the SoC and/or other processing means. In some implementations, the EM detector 295 may be a standalone component that can be configured to integrate some or all of the functionality of the voice command analysis unit 270, such as that illustrated in FIG. 11. Furthermore, the EM detector 295 may also include means for detecting anomalous EM emissions that may be indicative of a voice command being issued electronically.

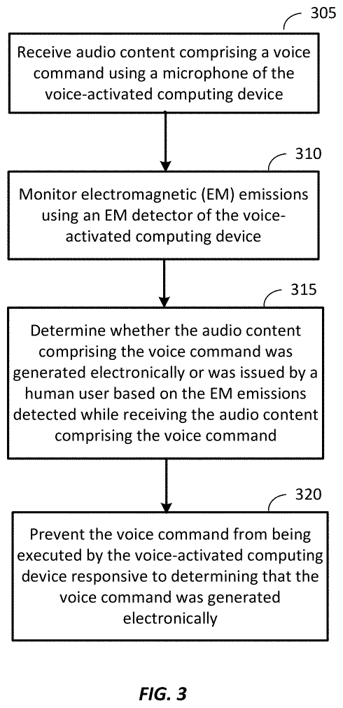

The voice command analysis unit 270 can provide means for performing the various example implementations discussed herein unless otherwise specified, such as the techniques illustrated in FIGS. 3-9. For example, the voice command analysis unit 270 can provide the means for detecting a voice command in audio content received by the computing device, means for monitoring EM emissions using the EM detector 295 or other sensor(s) 290 of the computing device 200, means for determining whether the voice command was issued electronically or by a human user, and means for correlating changes in the audio content with changes in the EM emissions to determine whether the voice command was issued electronically. The voice command analysis unit 270 can also include means for determining a security indicator based on the correlation of changes in EM emissions and changes in the audio content in which the voice command was issued. The voice command analysis unit 270 can also comprise means for calibrating the EM detector to generate baseline EM emissions. The voice command analysis unit 270 can comprise means for detecting EM emissions generated by the voice-activated computing device to generate the baseline EM emissions. The voice command analysis unit 270 can also comprise means for subtracting the baseline EM emissions from the EM emissions before correlating the changes in the audio content with the changes in the EM emissions. The functionality of the voice command analysis unit 270 can be implemented by hardware components of the TEE 280, the processor 210, processor executable code that is executed by the TEE 280 and/or the processor 210, or a combination thereof. The voice command analysis unit 270 may be implemented in the TEE to prevent malicious software that may have been installed on the voice-activated computing device from interfering with the operation of the voice command analysis unit 270. In particular, this approach can be useful where the voice commands have been issued locally by the speaker of the computing device 200 by malicious code that has gained control of the speaker.

FIG. 11 is a functional block diagram of an example electromagnetic (EM) detector 1100 that can be used to implement the EM detector 295. The EM detector 1100 includes a processor and can be configured to perform correlation analysis of audio content and EM emissions to make a determination whether a voice command included in the audio content was issued electronically or by a human user. The EM detector 1100 can be configured to detect anomalous EM variations that may be indicative of the voice command being generated electronically rather than issued by a human user of the voice-activated computing device. The EM detector 1100 can be configured to be utilized with a smart speaker or other such voice-activated computing device. The EM detector 1100 can be configured to be integrated with the voice-activated computing device at the time of manufacturing or may be a separate accessory that can be added to the voice-activated computing device. The EM detector 1100 may be manufactured for or by the original equipment manufacturer (OEM) of the voice-activated computing device or may be a provided by a third-party manufacturer of accessories for the voice-activated computing device.

For the sake of simplicity, the various features/components/functions illustrated in the schematic boxes of FIG. 11 can be connected together using a common bus or are can be otherwise operatively coupled together. Other connections, mechanisms, features, functions, or the like, may be provided and adapted as necessary to operatively couple and configure the EM detector 1100. Furthermore, one or more of the features or functions illustrated in the example of FIG. 11 may be further subdivided, or two or more of the features or functions illustrated in FIG. 11 may be combined. Additionally, one or more of the features or functions illustrated in FIG. 11 may be excluded.

As shown, the EM detector 1100 can include a data interface 1105 that can be configured to provide wired and/or wireless network connectivity to a voice-activated computing device, such as those illustrated in FIGS. 1 and 2. The data interface can be used to send data from EM detector 1100 to the voice-activated computing device and to receive data from the voice-activated computing device. The data interface 1105 can include a wireless transceiver for sending and receiving data wirelessly. The wireless transceiver can be configured to use various wireless protocols, including but not limited to BLUETOOTH, ZIGBEE, wireless local access network (WLAN), wireless personal area network (WPAN), wireless sensor network (WSN), and/or other wireless communication protocols. The data interface 1105 can include one or more ports that can be used to establish a wired connection between the EM detector 1100 and the voice-activated computing device, including but not limited to a Universal Serial Bus (USB) connection. The data interface 1105 can be configured to communicate with the voice-activated computing device via one or more GPIO pins. Other type of wired and/or wireless connections may also be provided for connecting the EM detector 1100 to the voice-activated computing device and/or other devices.

The processor(s) (also referred to as a controller) 1110 may be connected to the memory 1115, the voice command analysis unit 1170, anomalous emissions detection unit 1195, the user interface 1150, and the data interface 1105. The processor 1110 may include one or more microprocessors, microcontrollers, and/or digital signal processors that provide processing functions, as well as other calculation and control functionality. The processor 1110 can be coupled to storage media (e.g., memory) 1115 for storing data and software instructions for executing programmed functionality within the computing device, such as operating system software 1125 for operating the EM detector 1100 and EM data 1120 generated by the EM detector 1100. The memory 1115 may be on-board the processor 1110 (e.g., within the same integrated circuit package), and/or the memory may be external memory to the processor and functionally coupled over a data bus.

A number of software modules and data tables may reside in memory 1115 and may be utilized by the processor 1110 in order to manage, create, and/or remove content from the EM detector 1100 and/or perform device control functionality. The memory 115 may include one or more application modules (not shown) that may be executed by the processor 1110. It is to be noted that the functionality of the modules and/or data structures may be combined, separated, and/or be structured in different ways depending upon the implementation of the EM detector 1100.

The processor 1110 can include a trusted execution environment (TEE) 1180. The trusted execution environment 1180 can be used to implement a secure processing environment for executing secure software applications. The trusted execution environment 1180 can be implemented as a secure area of the processor 1110 that can be used to process and store sensitive data in an environment that is segregated from the rich execution environment in which the operating system and/or applications may be executed. The trusted execution environment 1180 can be configured to execute trusted applications that provide end-to-end security for sensitive data by enforcing confidentiality, integrity, and protection of the sensitive data stored therein. The trusted applications implemented in the trusted execution environment 280 can be configured to provide means for collecting and analyzing EM emissions data, receiving audio data, and/or for correlating changes to attributes in the EM emissions data to variations in EM emissions data collected by the EM detector.

The EM detector 1100 can be configured to include a user interface 250 that enables the user to configure the EM detector 1100. The user interface can comprise a voice interface and/or a graphical user interface. In some implementations, the voice-activated computing device may not include a display capable of display a graphical user interface but can be configured to allow a user to connect to the voice-activated computing device via an application on a smartphone, tablet, or other computing device that includes a display capable of displaying such a graphical user interface.

The EM detector 1100 can include sensor(s) 290. The sensor(s) 290 can but are not limited to magnetometer(s), antenna(s), and/or other means for detecting variations in the EM emissions proximate to the EM detector 1100. The EM detector 1100 can also include microphone(s) and/or other audio receiving means for receiving audio content that may include voice commands issued to the voice-activated computing device.

The voice command analysis unit 1170 can provide means for performing the various example implementations discussed herein unless otherwise specified, such as the techniques illustrated in FIGS. 3-9. The voice command analysis unit 1170 can be similar to voice command analysis unit discussed above with respect to the computing device 200. In some implementations, the voice-activated computing device may lack the functionality associated with the voice command analysis unit and the EM detector 1100 may instead implement this functionality. In yet other implementations, both the EM detector 1100 and the voice activated computing device may implement the functionality of the voice command analysis unit and may each analyze audio content received at the voice-activated computing device and thee EM detector 1100 to make a determination whether a voice command was issued electronically or by a human user. The functionality of the voice command analysis unit 1170 can be implemented by hardware components of the TEE 1180, the processor 1110, processor executable code that is executed by the TEE 1180 and/or the processor 1110, or a combination thereof. The voice command analysis unit 1170 may be preferably implemented in the TEE 1180 to prevent an attacker from disabling the EM detector 1100 or otherwise prevent the EM detector 1100 from making a determination that a voice command has been issued electronically.

The EM detector 1100 can include an anomalous emissions detection unit 1195. The EM detector 1100 can include the anomalous emissions detection unit 1195 in addition to or instead of the voice command analysis unit 1170. The anomalous emissions detection unit 1195 can be configured to implement a band filter that is configured to identify abnormal EM variations that fall outside of a predetermined frequency band. The anomalous emissions detection unit 1195 can be configured to output a signal to the voice command analysis unit 1170 and/or to the voice command analysis unit 270 of the voice-activated computing device indicating that abnormal EM variations have been detected and the voice command analysis unit 1170 and/or the voice command analysis unit 270 can be configured to make a determination that the audio content and any voice commands included therein having been generated electronically rather than having been issued by a human user of the voice-activated computing device.

FIG. 3 is an example process for operating a voice-activated computing device according to the disclosure. The process illustrated in FIG. 3 can be implemented by the voice command analysis unit 270 and the EM detector 295 and/or the sensor(s) 290 of the voice-activated computing device 105 illustrated in FIG. 1 and/or the computing device 200 illustrated in FIG. 2. In some implementations, the EM detector 295 can be configured to implement, at least in part, the functionality of the voice command analysis unit 270.

Audio content comprising a voice command computing device can be received (stage 305). The process illustrated in FIG. 3 can be triggered upon detecting an audio input at the voice-activated computing device. The audio input can be detected by a microphone of the voice-activated computing device or by a microphone of the EM detector 295. The voice command analysis unit 270 can be configured to recognize a “wake up” word or phrase that, when spoken by a user, triggers the voice-activated computing device to enter into a listening mode where voice-activated computing device is configured to listen for voice command inputs from the user. The voice command analysis unit 270 can be configured to send a signal to the EM detector 295 responsive to identifying the wake up word or phrase to cause the EM detector to begin monitoring for variations in EM emissions that may be indicative of voice commands being electronically generated rather than being issued by a human user of the voice-activated computing device. In some implementations, the EM detector 295 can include a microphone or other audio sensing means and can be configured to recognize the wake up words or phrases used by the voice-activated computing device and/or configured to recognize commonly used wake up words or phrases for multiple types of voice-activated computing devices so that the EM detector 295 can be used with various voice-activated computing devices provided by different manufacturers or resellers.

In some implementations, the voice command analysis unit 270 and/or the EM detector 295 can be configured to monitor ambient noise proximate to the voice-activated computing device 105 in order to determine baseline audio data for the operating environment in which the voice-activated computing device 105 is disposed. The EM detector 295 can also be configured to monitor ambient EM activity for the operating environment. The baseline audio content and baseline EM data for the operating environment can be taken into account by the voice command analysis unit 270 and/or the EM detector 295 when determining whether a voice command was issued electronically or by a human user.

The voice command analysis unit 270 can be configured to buffer audio input into a protected memory location that is substantially in accessible to untrusted processes running on the voice-activated computing device. The voice command analysis unit 270 can be configured to buffer the audio input in a memory associated with the trusted execution environment 280 which is inaccessible to applications and processing running in the rich execution environment of the voice-activated computing device. The EM detector 295 can include a memory for buffering audio content received via a microphone or other audio sensors incorporated into the EM detector 295. The voice command analysis unit 270 and/or the EM detector 295 can be configured to detect the end of a voice command input by monitoring the frequency, amplitude, and/or other attributes of the audio signals received and detecting changes in the frequency, amplitude, and/or other attributes indicative that the speech input has been completed. The voice command analysis unit 270 can be configured to send the audio content to a server, such as the server 110, for analysis and identification of the voice command(s) (if any) included in the audio input. The voice command analysis unit 270 can also be configured to stream the audio content to the server 110 as it is received in order to provide as fast a response time as possible to the voice command(s) included in the audio content captured by the voice-activated computing device. The EM detector 295 need not process the audio content to identify the voice command(s) included therein. Identification of the voice command(s) is not required in order to make a determination whether the audio content that includes the voice command(s) has been issued electronically rather than by a human user.

Electromagnetic (EM) emissions can be monitored using the EM detector of the voice-activated computing device (stage 310). The EM detector 295 can begin monitoring EM emissions to identify variations in the EM emissions, such variations may be indicative of a voice command being generated electronically. The magnetometer of the voice-activated computing device can be configured to monitor for EM emissions in some implementations instead of or in addition to the EM detector 295. The monitoring for EM emissions can be triggered by the voice command analysis unit 270 and/or the EM detector 295 detecting the wake up word or phrase used to trigger the voice-activated computing device to enter into a mode where the voice-activated computing device is operable to receive voice commands. The EM detector 295 can be configured output EM emissions data that is received by the voice command analysis unit 270. The EM detector 295 can be configured to buffer the EM emissions data in a memory local to the EM detector 295 and/or to perform other analysis on the EM emission data. The voice command analysis unit 270 can be configured to send a signal to the EM detector 295 to provide the EM emissions data to the voice command analysis unit 270 responsive to the voice command analysis unit 270 determining that the voice command entry has been completed.

A determination can be made whether the audio content comprising the voice command was generated electronically or was issued by a human user based on the EM emissions detected while receiving the audio content comprising the voice command (stage 315). The voice command analysis unit 270 can be configured to correlate changes in pitch, frequency, and/or other attributes of the audio content received in stage 305 with variations in the magnetic field detected by the EM detector 295. Where variations in the magnetic field detected by the EM detector 295 are cotemporal with changes in the pitch, frequency, and/or other attributes of the audio content, such occurrences are indicative of the audio content and any voice commands contained therein as being electronically generated rather than having been issued by a human user. Accordingly, the voice command analysis unit 270 can be configured to generate a correlation score (also referred to herein as a “security indicator”) as a result of the correlation of the audio content and the EM emissions data. In some implementations, the voice command analysis unit 270 can be configured to calculate the security indicator using a correlation coefficient function that correlates changes to one or more attributes in the audio data with variations in the EM emissions in the EM data. The correlation coefficient function can be configured to determine a relationship between data points representing the same point in time from the audio data and the EM data to determine whether the changes in the audio data are correlated to the variations in the EM data. The correlation coefficient formula can be configured to return a value that is indicative of whether there is a correlation between changes in the audio content and the EM variations.

In one example implementation, the correlation function is configured to return a value ranging from ‘1’ (one) to ‘−1’ (negative one, where a value of ‘1’ represents a strong positive correlation, a value of ‘0’ (zero) represents no correlation at all, and a value of ‘−1’ represents a strong negative correlation. A correlation value of ‘1’ indicates that for every positive increase in one variable (e.g., increase in pitch, frequency, etc. of the audio content) there is a positive increase of a fixed proportion in the other variable (e.g., a corresponding increase in the magnetic field). A correlation value of ‘−1’ indicates that for every positive increase in one variable (e.g., increase in pitch, frequency, etc. of the audio content) there is a negative increase of a fixed proportion in the other variable (e.g., a corresponding decrease in the magnetic field). A value of zero indicates that for every increase no positive or negative increase occurs, which indicates that the two variables are not related.

The voice command analysis unit 270 can be configured to determine the absolute value of the value output by the correlation function in the preceding example. The voice command analysis unit 270 can be configured to compare the absolute value to a predetermined threshold value and to make a determination that the changes in the audio content are correlated to the EM variations responsive to the absolute value of the output of the correlation function exceeding the predetermined threshold value. A determination that the changes in the audio content are correlated to the EM variations is indicative of the audio content and any voice commands included therein having been generated electronically rather than having been issued by a human user of the voice-activated computing device.

The example correlation techniques and the specific values discussed herein are merely examples that are used to illustrates these concepts. The voice command analysis unit 270 can be configured to utilize other correlation techniques to determine whether a correlation exits between the changes in the audio content and the EM variations. Furthermore, in some implementations, the EM detector 295 can be configured to perform the correlation function discussed above in addition to or instead of the voice command analysis unit 270.

The EM detector 295 can also be configured to detect abnormal EM variations which may be indicative of the audio content comprising the voice command having been generated electronically using a loudspeaker, such as the example loudspeakers illustrated in FIGS. 10A and 10B. The EM detector 295 can be configured to include a band filter that is configured to identify abnormal EM variations that fall outside of a predetermined frequency band. The EM detector 295 can be configured to output a signal to the voice command analysis unit 270 indicating that abnormal EM variations have been detected and the voice command analysis unit 270 can be configured to make a determination that the audio content and any voice commands included therein having been generated electronically rather than having been issued by a human user of the voice-activated computing device. The EM detector 295 can be configured to detect the abnormal EM variations in addition to or instead of the correlation technique discussed above.

The voice command can be prevented from being executed by the voice-activated computing device responsive to determining that the voice command was generated electronically (stage 320). In response to determining that the voice command was issued electronically and not from a human user, the voice command analysis unit 270 can be configured to prevent the voice command from being executed by the voice-activated computing device. The voice command analysis unit 270 can be configured to perform one or more additional actions in response to determining that the voice command was issued electronically. The voice command analysis unit 270 can be configured to temporarily disable voice command input on the device. The voice command analysis unit 270 can be configured to require an authorization code, personal identification number (PIN), password, or pass phrase from an authorized user of the voice-activated computing device before the voice command analysis unit 270 will enable the voice command functionality of the device. The voice command analysis unit 270 can be configured to power down the device in response to determining that a voice-based attack is underway. The voice command analysis unit 270 can also be configured to initiate a scan on the voice-activated computing device for malicious software, to restore the voice-activated computing device to a previously known state, and/or to reinstall software and/or applications on the voice-activated computing device. The voice command analysis unit 270 can also be configured to run diagnostics on the voice-activated computing device to determine whether any other components of the device have been compromised or damaged. The voice command analysis unit 270 can also be configured to notify the server 110 and/or another trusted third party entity that the voice-activated computing device has been subjected to a voice-based attack and may be compromised. The trusted third party entity may be a service provider associated with the voice-activated computing device that analyzes voice command inputs received at the voice-activated computing device, and/or provides other services to the voice-activated computing device, such as providing data, conducting transactions on behalf of the user of the voice-activated computing device, and/or other such services. The trusted third party entity may be a home automation service provider that provides services related to controlling and monitoring of Internet-connected appliances and systems of the user's home or business. The voice command analysis unit 270 can also be configured to notify a user of the voice-activated computing device that the device may have been subjected to a voice-based attack so that the user may take measures to address the attack, such as determining whether any unauthorized activity has been conducted through the voice-activated computing device.

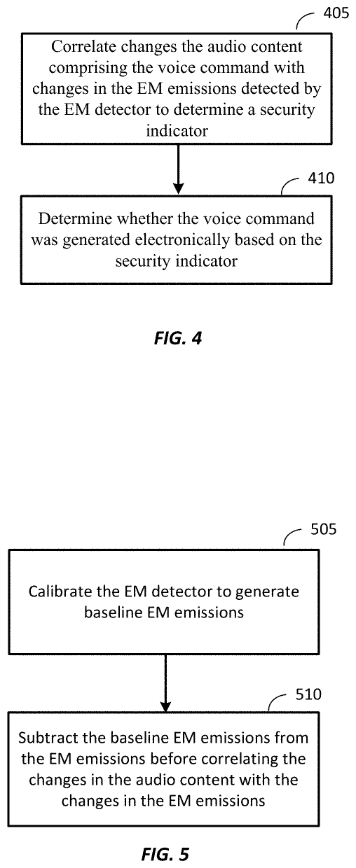

FIG. 4 is an example process for determining whether a voice command was generated electronically according to the disclosure. The process illustrated in FIG. 4 can be implemented by the voice command analysis unit 270 and the EM detector 295 and/or the sensor(s) 290 of the voice-activated computing device 105 illustrated in FIG. 1 and/or the computing device 200 illustrated in FIG. 2. The process illustrated in FIG. 4 can be used to implement, at least in part, stage 315 of the process illustrated in FIG. 3.

Changes in the audio content comprising the voice command can be correlated with changes in the EM emissions detected by the EM detector to determine a security indicator (stage 405). As discussed above, the voice command analysis unit 270 and/or the EM detector 295 can be configured to perform one or more correlation functions on the audio data and the EM data to determine whether changes to one or more attributes of the audio content correlate to EM variations included in the EM data collected by the EM detector 295 while the audio content was being collected.

A determination can be made whether the voice command was generated electronically based on the security indicator (stage 410). As discussed above, the output of the correlation function(s) can be compared to a predetermined threshold value. If the output of the correlation function(s) exceeds the predetermined threshold value, then the voice command analysis unit 270 can make a determination that the voice command has been generated electronically due to the correlations between the changes in the attributes of the audio content and the variations in the EM data. Such a correlation indicates that the voice command was generated using a loud speaker which caused the EM variations as the audio content comprising the voice command was played by the loud speaker. As such, the voice command analysis unit 270 can be configured to take one or more actions to prevent a voice-based attack on the voice-activated computing device.

FIG. 5 is an example process for calibrating an electromagnetic detector to generate baseline data was generated electronically according to the disclosure. The process illustrated in FIG. 5 can be implemented by the voice command analysis unit 270 and the EM detector 295 and/or the sensor(s) 290 of the voice-activated computing device 105 illustrated in FIG. 1 and/or the computing device 200 illustrated in FIG. 2. The process illustrated in FIG. 5 can be used to implement, at least in part, stage 315 of the process illustrated in FIG. 3.

The EM detector can be calibrated to generate baseline EM emissions information (stage 505). The EM detector 295 can be used to capture baseline EM emissions information for the operating environment in which the voice-activated computing device computing device is configured to operate. The baseline EM emissions information can include EM emissions from the voice-activated computing device itself and other sources of EM emissions in the operating environment of the voice-activated computing device. The speaker and/or other electronic components of the voice-activated computing device can generate a magnetic field that is detectable by the EM detector 295. Other electronic devices proximate to the EM detector may also be generating electronic emissions that are not indicative of a voice command being generated electronically. The EM detector 295 can be configured to capture a baseline EM emission reading and/or can be configured to capture baseline EM emissions patterns over time for the operating environment in which the voice-activated computing device is located.

The baseline EM emissions can be subtracted from the EM emissions before correlating the changes in the audio content with the changes in the EM emissions (stage 510). The EM emissions detected by the EM detector 295 while monitoring for EM emissions associated with a voice command, such as in stage 310 of the process of FIG. 3, can be adjusted to remove the baseline EM emissions so that the baseline EM emissions do not create a false positive situation in which a human-issued voice command is inadvertently classified as having been electronically generated. The voice command analysis unit 270 can be configured to adjust the EM emissions received from the EM detector 295 before performing a correlation with the audio data. The EM detector 295 be configured to adjust the EM emissions information generated by the EM detector 295 before sending the EM emissions to the voice command analysis unit 270. The voice command analysis unit 270 can also be configured to adjust the EM emissions information generated by the EM detector 295 before performing any correlation or filtering of the EM emissions information.

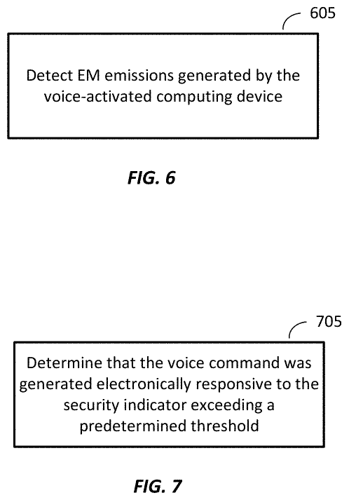

FIG. 6 is an example process for calibrating an electromagnetic detector to generate baseline data was generated electronically according to the disclosure. The process illustrated in FIG. 6 can be implemented by the voice command analysis unit 270 and the EM detector 295 and/or the sensor(s) 290 of the voice-activated computing device 105 illustrated in FIG. 1 and/or the computing device 200 illustrated in FIG. 2. The process illustrated in FIG. 6 can be used to implement, at least in part, stage 505 of the process illustrated in FIG. 5.

Electromagnetic emissions generated by the voice-activated computing device can be detected (stage 605). Components of the voice-activated computing device may generate EM emissions that can be detected by the EM detector 295 and/or the magnetometer of the voice-activated computing device. The EM emissions may interfere with the ability of the EM detector 295 and/or the voice command analysis unit 270 to make a determination whether audio content that includes a voice command was generated electronically or was issued by a human user. To counter this problem, a configuration process can be executed by the EM detector and/or the voice command analysis unit 270 in which the EM detector 295 and/or the magnetometer of the voice-activated computing device are configured to monitor EM emissions for a predetermined period of time to generate baseline EM emission data for the voice-activated computing device. EM emissions for other electronic devices proximate to the voice-activated computing device depending upon the sensitivity of the device collecting the baseline data (e.g., the EM detector 295 or the magnetometer). The baseline EM data can be used to establish what the EM emissions in the operating environment of the voice-activated computing device are expected to be. The configuration process to establish the EM emissions can be performed periodically by the voice-activated computing device. The configuration process can be performed each time that the voice-activated computing device is powered up and/or rebooted.

FIG. 7 is an example process for determining whether a voice command was generated electronically according to the disclosure. The process illustrated in FIG. 7 can be implemented by the voice command analysis unit 270 and the EM detector 295 and/or the sensor(s) 290 of the voice-activated computing device 105 illustrated in FIG. 1 and/or the computing device 200 illustrated in FIG. 2. The process illustrated in FIG. 7 can be used to implement, at least in part, stage 315 of the process illustrated in FIG. 3.

A determination that the voice command was generated electronically can be made responsive to the security indicator exceeding a predetermined threshold (stage 705). As discussed above, the voice command analysis unit 270 or the EM detector 295 can be configured to generate a correlation score or security indicator resulting from the correlation of the audio content and the EM emissions data. The security indicator can comprise a range of values that are indicative of the relationship between changes in attributes of the audio data comprising the voice command and EM variations included in the EM data. The voice command analysis unit 270 can be configured to make a determination that the voice command was issued electronically responsive to the security indicator exceeding the predetermined threshold value.

The threshold value may be determined by a manufacturer or reseller of the voice-activated computing device. The threshold value may also be determined by a service provider associated with the voice-activated computing device that provides voice-command analysis and identification on audio content captured by the voice-activated computing device. The threshold value may also be determined by a user of the voice-activated computing device. The voice-activated computing device can be configured to provide a user interface that enables the user to configure security settings of the voice-activated computing device. The user interface can comprise a voice interface and/or a graphical user interface. In some implementations, the voice-activated computing device may not include a display capable of display a graphical user interface but can be configured to allow a user to connect to the voice-activated computing device via an application on a smartphone, tablet, or other computing device that includes a display capable of displaying such a graphical user interface.

FIG. 8 is an example process for determining whether a voice command was generated electronically according to the disclosure. The process illustrated in FIG. 8 can be implemented by the voice command analysis unit 270 and the EM detector 295 and/or the sensor(s) 290 of the voice-activated computing device 105 illustrated in FIG. 1 and/or the computing device 200 illustrated in FIG. 2. The process illustrated in FIG. 8 can be used to implement, at least in part, stage 315 of the process illustrated in FIG. 3.

The audio content and information regarding the EM emissions can be sent to a remote server for analysis (stage 805). In some implementations, the audio content and the EM emissions data can be sent to a remote server for analysis, such as the server 110. The server 110 can be associated with a service provider that provides various services to the voice-activated computing device, such as voice-command analysis and identification on audio content captured by the voice-activated computing device that includes analyzing EM emissions data associated with the audio content captured by the voice-activated computing device. The service provider may also provide security services for the voice-activated computing device. The server 110 can be configured to receive the audio content and the EM emissions data collected by the voice command analysis unit 270, the EM detector 295, and/or the magnetometer of voice-activated computing device and to perform correlation analysis on the received data similar to that discussed above in the preceding example implementations in which the voice command analysis unit 270 and/or the EM detector 295 performed correlation analysis on the audio and EM emission data. In some implementations, the voice command analysis unit 270 and/or the EM detector 295 can be configured to perform correlation analysis on the audio and EM emission data and the audio and EM emission data can be sent to the server 110 as well for analysis.

An indication can be received from the server whether the voice command was generated electronically or by a human user from the remote server (stage 810). The server 110 can be configured to generate a security indicator similar to that generated by the voice command analysis unit 270 and/or the EM detector 295 in the preceding examples. In some implementations, the security indicator may be a binary value indicating that the voice command was issued electronically or was not issued electronically. In other implementations, the security indicator can comprise a range of values that indicative of the relationship between changes in attributes of the audio data comprising the voice command and EM variations included in the EM data, and the voice command analysis unit 270 can be configured to compare the security indicator to a predetermined threshold to determine whether the voice command was issued electronically or was issued by a human user. In some implementations, the server 110 and the voice command analysis unit 270 and/or the EM detector 295 can be configured to determine a security indicator. In such implementations, the voice command analysis unit 270 may be configured to determine an average of each of these security indicators, and to determine whether the voice command was issued electronically or issued by a human user based on whether the average of the security indicators exceeds the predetermined threshold.

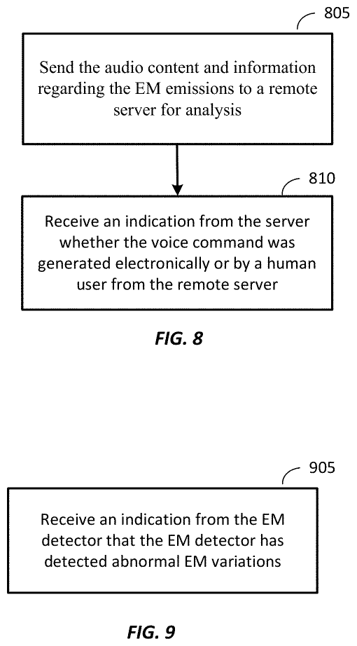

FIG. 9 is an example process for determining whether a voice command was generated electronically according to the disclosure. The process illustrated in FIG. 9 can be implemented by the voice command analysis unit 270 and the EM detector 295 and/or the sensor(s) 290 of the voice-activated computing device 105 illustrated in FIG. 1 and/or the computing device 200 illustrated in FIG. 2. The process illustrated in FIG. 9 can be used to implement, at least in part, stage 315 of the process illustrated in FIG. 3.

An indication can be received from the EM detector that the EM detector has detected abnormal EM variations (stage 905). As discussed above, the EM detector 295 can be configured to include a filter that is configured to generate a signal responsive to EM variations being outside of an expected range. The EM detector 295 can output a signal to the voice command analysis unit 270 that abnormal EM variations have been detected, which may be indicative of a voice command being issued electronically by another device proximate to the voice-activated computing device.

If implemented in-part by hardware or firmware along with software, the functions can be stored as one or more instructions or code on a computer-readable medium. Examples include computer-readable media encoded with a data structure and computer-readable media encoded with a computer program. Computer-readable media includes physical computer storage media. A storage medium can be any available medium that can be accessed by a computer. By way of example, and not limitation, such computer-readable media can comprise RAM, ROM, EEPROM, CD-ROM or other optical disk storage, magnetic disk storage, semiconductor storage, or other storage devices, or any other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

Unless defined otherwise, all technical and scientific terms used herein have the same meaning as commonly or conventionally understood. As used herein, the articles “a” and “an” refer to one or to more than one (i.e., to at least one) of the grammatical object of the article. By way of example, “an element” means one element or more than one element. “About” and/or “approximately” as used herein when referring to a measurable value such as an amount, a temporal duration, and the like, encompasses variations of ±20% or ±10%, ±5%, or +0.1% from the specified value, as such variations are appropriate in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or +0.1% from the specified value, as such variations are appropriate in the context of the systems, devices, circuits, methods, and other implementations described herein.

As used herein, including in the claims, “or” as used in a list of items prefaced by “at least one of” or “one or more of” indicates a disjunctive list such that, for example, a list of “at least one of A, B, or C” means A or B or C or AB or AC or BC or ABC (i.e., A and B and C), or combinations with more than one feature (e.g., AA, AAB, ABBC, etc.). Also, as used herein, unless otherwise stated, a statement that a function or operation is “based on” an item or condition means that the function or operation is based on the stated item or condition and can be based on one or more items and/or conditions in addition to the stated item or condition.

What is claimed is:

1. A method for operating a voice-activated computing device, the method comprising:
receiving audio content comprising a voice command;
monitoring electromagnetic (EM) emissions using an EM detector of the voice-activated computing device;
determining whether the audio content comprising the voice command was generated electronically or was issued by a human user based on the EM emissions detected while receiving the audio content comprising the voice command; and
preventing the voice command from being executed by the voice-activated computing device responsive to determining that the voice command was generated electronically.

2. The method of claim 1, wherein determining whether the audio content comprising the voice command was issued electronically or by a human user further comprises:
correlating changes in the audio content comprising the voice command with changes in the EM emissions detected by the EM detector to determine a security indicator; and
determining whether the voice command was generated electronically based on the security indicator.

3. The method of claim 2, wherein the changes in the audio content comprise changes in at least one of the volume and the frequency of the audio content.

4. The method of claim 2, further comprising:
calibrating the EM detector to generate baseline EM emissions; and wherein correlating the changes in the audio content comprising the voice command with changes in the EM emissions further comprises subtracting the baseline EM emissions from the EM emissions before correlating the changes in the audio content with the changes in the EM emissions.

5. The method of claim 4, wherein calibrating the EM detector to generate the baseline EM emissions comprises detecting EM emissions generated by the voice-activated computing device.

6. The method of claim 2, further comprising:
determining that the voice command was generated electronically responsive to the security indicator exceeding a predetermined threshold.

7. The method of claim 1, wherein determining whether the audio content comprising the voice command was issued electronically or by a human user further comprises:
sending the audio content and information regarding the EM emissions to a remote server for analysis; and
receiving an indication from the server whether the voice command was generated electronically or by a human user from the remote server.

8. The method of claim 1, wherein determining whether the audio content comprising the voice command was issued electronically or by a human user further comprises:
receiving an indication from the EM detector that the EM detector has detected abnormal EM variations.

9. A voice-activated computing device comprising:
means for receiving audio content comprising a voice command using means for receiving sound;
means for monitoring electromagnetic (EM) emissions;
means for determining whether the audio content comprising the voice command was generated electronically or was issued by a human user based on the EM emissions detected while receiving the audio content comprising the voice command; and
means for preventing the voice command from being executed by the voice-activated computing device responsive to determining that the voice command was generated electronically.

10. The voice-activated computing device of claim 9, wherein the means for determining whether the audio content comprising the voice command was issued electronically or by a human user further comprises:
means for correlating changes in the audio content comprising the voice command with changes in the EM emissions detected by the means for detecting EM emissions to determine a security indicator; and
means for determining whether the voice command was generated electronically based on the security indicator.

11. The voice-activated computing device of claim 10, wherein the changes in the audio content comprise changes in at least one of the volume, the frequency, the cadence, and the voice pattern of the audio content.

12. The voice-activated computing device of claim 10, further comprising:
means for calibrating the means for detecting EM emissions to generate baseline EM emissions; and wherein the means for correlating the changes in the audio content comprising the voice command with changes in the EM emissions further comprises means for subtracting the baseline EM emissions from the EM emissions before correlating the changes in the audio content with the changes in the EM emissions.

13. The voice-activated computing device of claim 12, wherein the means for calibrating the means for detecting EM emissions to generate the baseline EM emissions comprises means for detecting EM emissions generated by the voice-activated computing device.

14. The voice-activated computing device of claim 10, further comprising:
means for determining that the voice command was generated electronically responsive to the security indicator exceeding a predetermined threshold.

15. The voice-activated computing device of claim 9, wherein the means for determining whether the audio content comprising the voice command was issued electronically or by a human user further comprises:
means for sending the audio content and information regarding the EM emissions to a remote server for analysis; and
means for receiving an indication from the server whether the voice command was generated electronically or by a human user from the remote server.

16. The voice-activated computing device of claim 9, wherein the means for determining whether the audio content comprising the voice command was issued electronically or by a human user further comprises:
means for receiving an indication from the EM detector that the EM detector has detected abnormal EM variations.

17. A voice-activated computing device comprising:
an electromagnetic (EM) detector configured to monitor for EM emissions;
a microphone; and
a processor communicatively coupled to the EM detector and the microphone, the processor configured to:
receive audio content comprising a voice command using the microphone;
monitor electromagnetic (EM) emissions using the EM detector;
determine whether the audio content comprising the voice command was generated electronically or was issued by a human user based on the EM emissions detected while receiving the audio content comprising the voice command; and
prevent the voice command from being executed by the voice-activated computing device responsive to determining that the voice command was generated electronically.

18. The voice-activated computing device of claim 17, wherein the processor being configured to determine whether the audio content comprising the voice command was issued electronically or by a human user is further configured to:
correlate changes in the audio content comprising the voice command with changes in the EM emissions detected by the EM detector to determine a security indicator; and
determine whether the voice command was generated electronically based on the security indicator.

19. The voice-activated computing device of claim 18, wherein the changes in the audio content comprise changes in at least one of the volume, the frequency, the cadence, and the voice pattern of the audio content.

20. The voice-activated computing device of claim 18, wherein the processor is further configured to:
calibrate the EM detector to generate baseline EM emissions; and wherein the processor being configured to correlate the changes in the audio content comprising the voice command with changes in the EM emissions is further configured to subtract the baseline EM emissions from the EM emissions before correlating the changes in the audio content with the changes in the EM emissions.

21. The computing device voice-activated computing device of claim 20, wherein the processor being configured to calibrate the EM detector to generate the baseline EM emissions is further configured to detect, using the EM detector, EM emissions generated by the voice-activated computing device.

22. The voice-activated computing device of claim 18, wherein the processor is further configured to:
determine that the voice command was generated electronically responsive to the security indicator exceeding a predetermined threshold.

23. The voice-activated computing device of claim 17, wherein the processor being configured to determine whether the audio content comprising the voice command was issued electronically or by a human user is further configured to:
send the audio content and information regarding the EM emissions to a remote server for analysis; and
receive an indication from the server whether the voice command was generated electronically or by a human user from the remote server.

24. The voice-activated computing device of claim 17, wherein the processor being configured to determine whether the audio content comprising the voice command was issued electronically or by a human user is further configured to:
receive an indication from the EM detector that the EM detector has detected abnormal EM variations.

25. A non-transitory, computer-readable medium, having stored thereon computer-readable instructions for operating a voice-activated computing device, comprising instructions configured to cause the voice-activated computing device to:
receive audio content comprising a voice command;
monitor electromagnetic (EM) emissions using an EM detector of the voice-activated computing device;
determine whether the audio content comprising the voice command was generated electronically or was issued by a human user based on the EM emissions detected while receiving the audio content comprising the voice command; and
prevent the voice command from being executed by the voice-activated computing device responsive to determining that the voice command was generated electronically.

26. The non-transitory, computer-readable medium of claim 25, wherein the code to cause the voice-activated computing device to determine whether the audio content comprising the voice command was issued electronically or by a human user further comprise instructions configured to cause the voice-activated computing device to:
correlate changes in the audio content comprising the voice command with changes in the EM emissions detected by the EM detector to determine a security indicator; and
determine whether the voice command was generated electronically based on the security indicator.

27. The non-transitory, computer-readable medium of claim 26, wherein the changes in the audio content comprise changes in at least one of the volume, the frequency, the cadence, and the voice pattern of the audio content.

28. The non-transitory, computer-readable medium of claim 26, further comprising instructions configured to cause the voice-activated computing device to:
calibrate the EM detector to generate baseline EM emissions; and wherein correlating the changes in the audio content comprising the voice command with changes in the EM emissions further comprises subtracting the baseline EM emissions from the EM emissions before correlating the changes in the audio content with the changes in the EM emissions.

29. The non-transitory, computer-readable medium of claim 28, wherein the instructions configured to cause the voice-activated computing device to calibrate the EM detector to generate the baseline EM emissions further comprise instructions configured to cause the voice-activated computing device to detect EM emissions generated by the voice-activated computing device.

30. The non-transitory, computer-readable medium of claim 26, further comprising instructions configured to cause the voice-activated computing device to:
determine that the voice command was generated electronically responsive to the security indicator exceeding a predetermined threshold.
